(19) United States
(12) Patent Application Publication
(10) Pub. No.: US 2008/0017107 A1
(43) Pub. Date: Jan. 24, 2008

(54) Plasma processing apparatus

(76) Inventors: Masatsugu Arai, Ibaraki-ken (JP); Ryujiro Udo, Ibaraki-ken (JP); Seiichiro Kanno, Ibaraki-ken (JP); Tsuyoshi Yoshida, Hikari-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/798,646

(22) Filed: May 15, 2007

Related U.S. Application Data
(63) Continuation of application No. 10/795,350, filed on Mar. 9, 2004, now abandoned.

(30) Foreign Application Priority Data
Sep. 3, 2003 (JP) 2003-311730

(51) Int. Cl. C23C 16/00

(52) U.S. Cl. 118/712

(57) ABSTRACT

A plasma processing apparatus having an electrostatic chucking electrode that allows temperature control of a semiconductor wafer during etching process with high efficiency comprises: a holder stage comprising an electrode block S having a dielectric film 4 on the surface thereof and a coolant flow passage 6 therein, in which temperature control is performed while holding a semiconductor wafer W on the dielectric film on the surface of the electrode block; and a cooling cycle 50 including a compressor 52, a condenser 55, an expansion valve 53, a heat exchanger 54 having a heater built therein, and an evaporator, wherein the temperature control of the electrode block S is performed by using a direct-expansion-type temperature controller in which the electrode block S is used as the evaporator of the cooling cycle, and the coolant is directly circulated and expanded inside the electrode block.

### BACKGROUND OF THE INVENTION

1. Field of the Invention

The present invention relates to a plasma processing apparatus that is used in fine processing such as a semiconductor manufacturing process, and more particularly to a plasma processing apparatus comprising a holder stage for placing a semiconductor wafer.

2. Description of the Related Art

Recent semiconductor integrated circuits that have more integrated features than ever have finer circuit patterns, and hence requires better accuracy in process dimension than ever. Moreover, measures are also required to increase throughputs and to process workpieces, such as semiconductor wafers, having larger sizes. Thus, higher electric power is required to be supplied to plasma processing apparatuses. In particular, in the case of a plasma processing apparatus for etching dielectrics, the electric power supplied during plasma generation tends to be increased so as to enhance the etching rate. Since most of the electric power supplied to a plasma processing apparatus is converted to heat, a temperature adjustment unit (a cooling unit) with high efficiency and high capacity is required in an electrostatic chucking electrode (a holder stage), for example, that controls the temperature of a semiconductor wafer with high accuracy. In addition to the requirement for high efficiency, the temperature adjustment unit is also required to occupy only a small installation area and to cause minimum environmental influence.

The temperature control of a semiconductor wafer in a plasma processing apparatus is typically performed by controlling the surface temperature of an electrostatic chucking electrode, and a method for allowing such temperature control in processing has been proposed. In this conventional method, temperature control for an electrostatic chucking electrode is performed by circulating a thermal medium in an electrode block that is a constituent member of the electrostatic chucking electrode. The circulated thermal medium, which is typically an inert fluorine-based liquid, is maintained at a predetermined temperature by, for example, cooling in a cooling cycle using chlorofluorocarbon or heating using a heater. A temperature unit that circulates such a thermal medium can have small temperature variation owing to the thermal capacity of the circulated thermal medium itself, but can also have a poor temperature response. Moreover, the temperature unit uses heat inefficiently since the temperature of the thermal medium is controlled via a heat exchanger, and it takes up large space since it requires a pump for circulating the thermal medium due to the apparatus configuration. (See, for example, Patent Document 1.)

Because of the above reasons, a temperature adjustment unit is proposed, which, instead of using an inert fluorine-based thermal medium, uses propane gas as a coolant that is directly fed to the inside of an electrostatic chucking electrode and circulated therein. (See, for example, Patent Document 2.)

[Patent Document 1] Japanese Patent Laid-Open No. 2001-257253

[Patent Document 2] Japanese Patent Laid-Open No. 2003-174016

According to the above described conventional techniques, the temperature adjustment units for electrostatic chucking electrodes were not so adequately devised to achieve temperature control of a electrostatic chucking electrode with high efficiency and high accuracy.

As described above, for example, the temperature adjustment unit of Patent Document 1 maintains the circulated thermal medium at a predetermined temperature via a heat exchanger in the thermal adjustment unit, and thus has poor thermal efficiency and requires a pump to circulate the thermal medium. It also requires a large amount of thermal medium and has poor temperature response.

On the other hand, the method disclosed in Patent Document 2 lacks to describe the detailed structure of an electrostatic chucking electrode. For example, there is fear that the electrode block may deform into a convex shape when the coolant is directly circulated inside the electrostatic chucking electrode, due to the high pressure of the coolant.

It is an object of the present invention to provide an electrostatic chucking electrode (a holder stage) and a temperature adjustment unit that allow to control the temperature of a semiconductor wafer during etching process with high efficiency.

### SUMMARY OF THE INVENTION

To solve the above problems, the present invention provides a plasma processing apparatus comprising: a holder stage comprising an electrode block having a dielectric film on the surface thereof and a coolant flow passage formed therein, for holding a semiconductor wafer on the dielectric film on the surface of the electrode block and performing temperature control; and a cooling cycle including a compressor, a condenser, an expansion valve and an evaporator; wherein the temperature control of the electrode block is performed by using a direct-expansion-type temperature controller in which the electrode block is used as the evaporator of the cooling cycle, and the coolant is directly circulated and expanded inside the electrode block.

In the plasma processing apparatus of the present invention, the direct-expansion-type temperature controller may comprise a heat exchanger having a heater built therein and disposed upstream of the evaporator of the cooling cycle, for controlling the electrode block to a predetermined temperature, regardless of whether plasma is generated or not.

In the plasma processing apparatus of the present invention, the direct-expansion-type temperature controller may monitor the temperature of the electrode block either directly or indirectly, and may control the temperature of the electrode block to a predetermined temperature based on the monitored signal.

The plasma processing apparatus of the present invention may further comprise a heat dissipation plate provided immediately above the coolant flow passage in the electrode block. The plasma processing apparatus of the present invention may further comprise a bypassing pipeline provided parallel to the electrode block for allowing the coolant to bypass the electrode block.

The plasma processing apparatus of the present invention may further comprise: a first open/close valve provided between the expansion valve and a coolant inlet of the electrode block; a gas supply valve for supplying an inert gas, provided between the first open/close valve and the coolant inlet of the electrode block; a second open/close valve provided between a coolant outlet of the electrode block and the compressor; a discharge valve connected to a vacuum pump, provided between the second open/close valve and the coolant outlet of the electrode block; and a container for containing the coolant, provided between the compressor and the condenser, wherein the coolant inlet of the electrode block and the first open/close valve are connected in a disconnectable manner, and the coolant outlet and the second open/close valve are connected in a disconnectable manner.

### BRIEF DESCRIPTION OF THE DRAWINGS

FIG. 1 is a diagram illustrating a configuration of a plasma processing apparatus according to the present invention;

FIG. 2 is a diagram illustrating a temperature adjustment unit of a plasma processing apparatus according to the present invention;

FIG. 3 shows diagrams illustrating a configuration of temperature adjustment units;

FIG. 4 is a diagram illustrating the relation between the temperature and heat transfer coefficient of the coolant;

FIG. 5 shows cross-sectional views of an exemplary coolant flow passage of an electrostatic chucking electrode;

FIG. 6 is a diagram illustrating the relation between the temperature and heat transfer coefficient in a coolant passage;

FIG. 7 is a cross-sectional view illustrating a configuration of an electrode block;

FIG. 8 is a cross-sectional view illustrating another exemplary coolant passage of an electrostatic chucking electrode;

FIG. 9 is a cross-sectional view illustrating yet another exemplary coolant passage of an electrostatic chucking electrode; and

FIG. 10 is a diagram illustrating a configuration that allows the replacement of an electrostatic chucking electrode.

### DETAILED DESCRIPTION OF THE PREFERRED EMBODIMENTS

A plasma processing apparatus according to the present invention will be described in detail with reference to the drawings.

[Configuration of the Plasma Processing Apparatus]

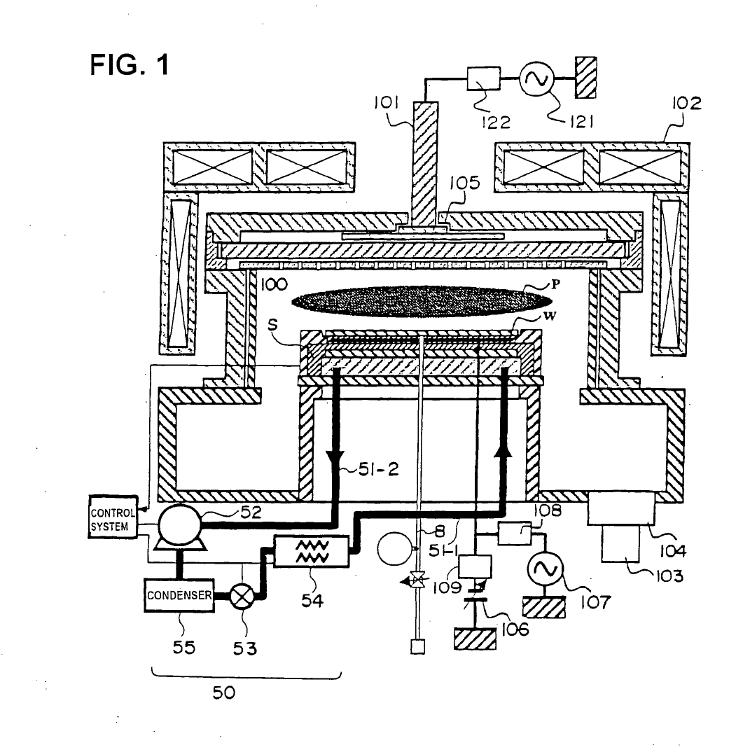

FIG. 1 is a cross-sectional view of a plasma processing apparatus of one embodiment of the present invention. The plasma processing apparatus in FIG. 1 comprises a processing chamber 100, an antenna 101 disposed above the processing chamber 100 for radiating electromagnetic waves, and a holder stage S for placing a workpiece such as a semiconductor wafer W, disposed at the lower area of the processing chamber 100. The antenna 101 is supported on a housing 105 formed as a part of a vacuum container, and is placed in parallel confronting relations to the holder stage S. On the periphery of the processing chamber 100 is provided magnetic field generation means 102 consisting of electromagnetic coils and yokes. The holder stage S is so-called an electrostatic chucking electrode, and will be thus referred to as electrostatic chucking electrode S hereinafter.

The processing chanter 100 is a vacuum container that can generate a vacuum with a pressure on the order of 1/1000 Pa through use of a vacuum exhaustion system 103. Processing gases for use in processes such as etching workpieces or depositing films are supplied into the processing chamber 100 with predetermined flowrates and mixing ratio from gas supply means (not shown), and the pressure in the processing chamber 100 is controlled via the vacuum exhaustion system 103 and an exhaustion regulating means 104. In general, plasma processing apparatuses are often used with the processing pressure during etching being adjusted in the range of 0.1 Pa to 10 Pa.

An antenna power supply 121 is connected to the antenna 101 via a matching circuit 122. The antenna power supply 121 can supply electric power with a frequency in the UHF band, from 300 MHz to 1 GHz, and the frequency in this embodiment for the antenna power source is set to 450 MHz. To the electrostatic chucking electrode S are connected a high-voltage power supply 106 for electrostatic chucking, and a biasing power supply 107 for supplying biasing power in the range of 200 kHz to 13.56 MHz, for example, via a matching circuit 108. In this embodiment, the frequency of the biasing power source 107 is set to 2 MHz.

[Configuration of Electrostatic Chucking Electrode S]

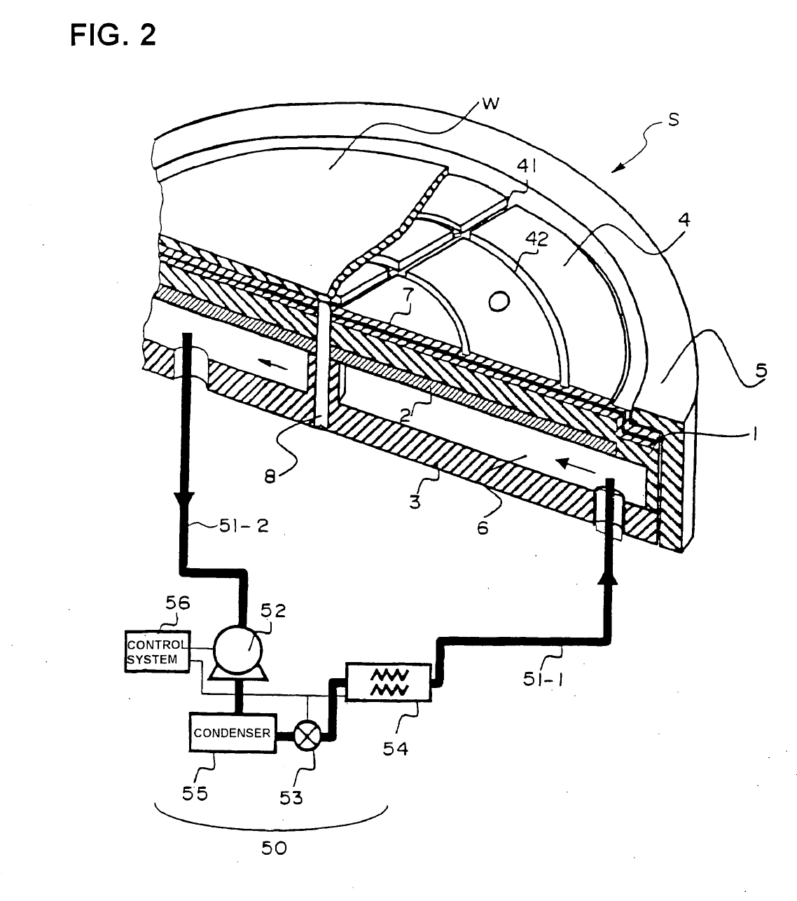

FIG. 2 is a perspective view or the electrostatic chucking electrode S used as a holder stage for a semiconductor wafer W with a portion thereof shown in cross-section. With reference to this figure, a structure of the electrostatic chucking electrode S will be described in detail. As shown in FIG. 2, the electrostatic chucking electrode S comprises, in an electrode block 1 of titanium, a plate 2 of aluminum for heat dissipation, a guide member 3 of titanium, a dielectric film 4, and an electrode cover 5 of ceramics, in which the electrode block 1, plate 2 and guide member 3 are bonded together with metal solder having a low melting point, and on the top surface thereof is bonded the dielectric film 4 with a silicon based adhesive.

The size of the electrostatic chucking electrode S may be 340 mm in diameter and 40 mm in total thickness for processing a semiconductor wafer of 12 inches (diameter of 300 mm). A flow passage 6 for coolant is provided in the electrode block 1, and an electrode 7 of metal is embedded in the dielectric film 4. The high voltage power supply 106 and biasing power supply 107 are connected to the electrode 7 in the dielectric film 4. As shown in FIG. 2, the dielectric film 4 has a linear slit 41 that extends radially and is in communication with a gas introduction hole B, and a plurality of concentric circular slits 42 in communication with the slit 41. He gas for transferring heat is provided through the gas introduction hole 8 and is filled to the backside of the semiconductor wafer W through the slits with uniform pressure (typically about 1000 Pa).

While the dielectric film 4 in this embodiment is formed of high-purity alumina ceramics with a thickness of 3 mm, the material and thickness of the dielectric film 4 are not limited to these, and a thickness of 0.1 mm to several mm may be selected if necessary when using, for example, synthetic resin.

A temperature adjustment unit 50 is used to control the temperature of the electrostatic chucking electrode S. The temperature adjustment unit 50 comprises a coolant pipeline 51 through which coolant is circulated, a compressor 52, an expansion valve 53, a heating unit 54 having a heater therein, a condenser 55, a control system 56, and a coolant passage 6 serving as an evaporator. The control system 56 is equipped with a control circuit that controls the compressor 52, the expansion valve 53 and the heating unit 54 while indirectly or directly monitoring the temperature of the electrode block 1, so that the electrode block 1 maintains a predetermined temperature.

[Temperature Control Mechanism of Electrostatic Chucking Electrode]

The principle for controlling the temperature of the electrostatic chucking electrode S in this embodiment will be described. The electrostatic chucking electrode S fastens a semiconductor wafer W thereon with coulomb force or Johnson-Lambeck force that is generated by applying high voltage to the dielectric film 4. There are two methods for applying high voltage: a monopolar type and a bipolar type. The monopolar method gives a uniform electric potential between the semiconductor wafer and the dielectric film. The bipolar method gives two or more electric potentials between the dielectric films. The present embodiment utilizes a monopolar-type electrostatic chucking electrode. However, it is possible to utilize either type.

The temperature of the semiconductor wafer W during etching process depends on the amount of heat coming in from plasma, the heat resistance of the He layer and the surface temperature of the electrostatic chucking electrode S. The surface temperature of the electrostatic chucking electrode S depends on the amount of heat coming in from plasma, the heat resistance within the electrode block 1, the heat resistance between the electrode block 1 and the coolant circulating in the electrode block 1, and the temperature of the circulating coolant.

[Operation of Plasma Processing Apparatus]

A specific process for using the plasma processing apparatus according to this embodiment for etching silicon, for example, will now be described. Referring to FIG. 1, first, a semiconductor wafer W, which is a workpiece to be processed, is loaded from a workpiece loading mechanism (not shown) to the processing chamber 100, and then placed on and fastened to the electrostatic chucking electrode S with the height of the electrostatic chucking electrode S adjusted, if necessary, to provide a predetermined gap. Then, gases required for etching the semiconductor wafer W, such as chlorine, hydrogen bromide and oxygen, are supplied from a gas supply means (not shown) into the processing chamber 100 with predetermined flow rates and mixing ratio. At the same time, the pressure in the processing chamber 100 is controlled to a predetermined processing pressure using the vacuum exhaust system 103 and exhaust control means 104. Then, electromagnetic waves are radiated from the antenna 101 by the supply of power from the antenna power supply 121 at 450 MHz. Then, the electromagnetic waves interact with a substantially horizontal magnetic field of 160 gausses (electron cyclotron resonance magnetic field strength corresponding to 450 MHz) generated in the processing chamber 100 by the magnetic field generation means 102, thereby generating plasma P in the processing chamber 100 to dissociate the processing gases and produce ions and radicals. Then, etching is performed while utilizing the biasing power from the biasing power supply 107 for the electrostatic chucking electrode S to control the composition and energy of ions and radicals in the plasma and while controlling the temperature of the semiconductor wafer W. At the end of the etching, the supply of electric power, magnetic field and processing gases is stopped to terminate the etching.

Note that the present invention can be embodied not only using the UHF-type plasma processing apparatus described above, but also using other types of plasma apparatuses.

[Details of Temperature Adjustment Unit]

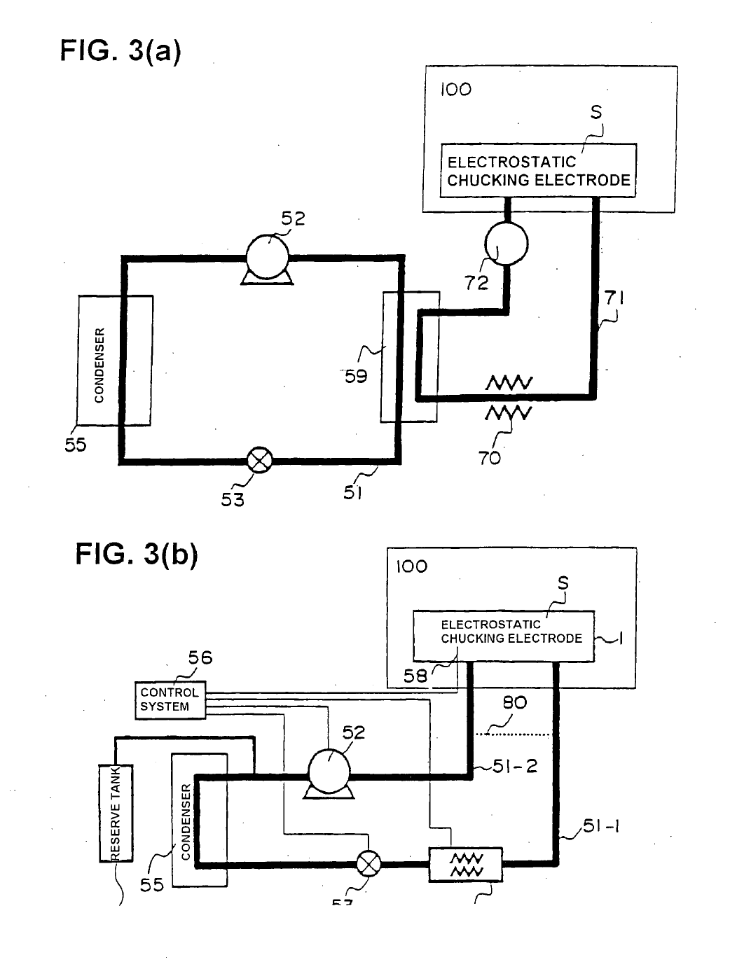

FIG. 3 shows a temperature adjustment unit according to the prior art and a temperature adjustment unit of the present invention for comparison. FIG. 3(a) shows a circulating-type temperature adjustment unit according to the prior art while FIG. 3(b) shows a temperature adjustment unit 50 according to the present invention.

The temperature adjustment unit shown in FIG. 3(a) comprises: a cooling cycle consisting of a coolant pipeline 51 through which cool ant such as chlorofluorocarbon circulates, a compressor 52, an expansion valve 53, a condenser 55, and a heat exchanger 59 serving as an evaporator; a pipeline 11 through which an inert fluorine-based thermal medium flows; a pump 72 for circulating the thermal medium; a heat exchanger 59 for performing heat exchange between the coolant and the thermal medium; and a heater 70 for heating the thermal medium. According to the prior art temperature adjustment unit, since the circulating thermal medium has a thermal capacity of its own, it is capable of minimizing the temperature variation, but suffers poor temperature response. The maximum acceptable temperature of a semiconductor wafer W corresponds to the heat resistant temperature of the resist formed on the surface of the wafer. Thus, when a large amount of heat is incoming from plasma, the temperature of the surface of the dielectric film 4 and hence the temperature of the circulating thermal medium must be lowered depending or the amount of incoming heat.

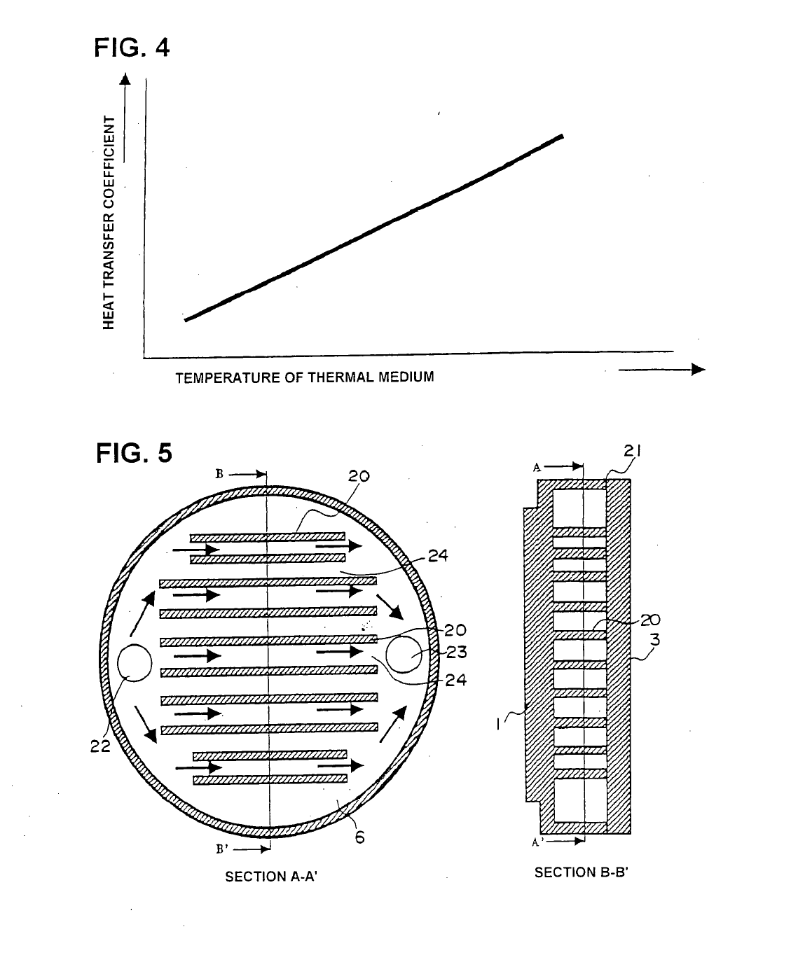

However, as shown in FIG. 4, as the temperature of the thermal medium falls, the viscosity of the thermal medium increases, so the heat transfer coefficient of the thermal medium with respect to the electrode block 1 is reduced. For example, the heat transfer coefficient of the thermal medium at 20° C. circulating at 4 L/min through a rectangular pipeline with a height of 15 mm and a width of 5 mm is approximately 800 W/m²K, while that of the thermal medium at 0° C. is reduced to 600 W/m²K (recalculated). This is also the case for the heat exchanger in the temperature adjustment unit, that is, the heat exchanger has poor thermal efficiency in lower thermal medium temperature, and thus the temperature adjustment unit can absorb only a small amount of heat. Consequently, the temperature of the circulating thermal medium may gradually increase.

On the other hand, the temperature adjustment unit 50 according to the present invention shown in FIG. 3(b), in which the coolant is directly circulated in the electrostatic chucking electrode S, comprises a coolant supplying pipeline 51-1, a coolant discharging pipeline 51-2, a compressor 52, an expansion valve 53, a heating unit 54 equipped with a heater, a condenser 55, a reserve tank 57 and a control system 56. The reserve tank 57 is provided in the temperature adjustment unit 50 in order to circulate a constant amount of coolant. The coolant absorbs heat during vaporization in the electrode block 1, and the vaporized coolant is then pressurized in the compressor 52 (to lower the boiling point), and cooled and condensed in the condenser 55.

In the plasma processing apparatus, the temperatures of the plasma processing chamber 100 and the electrostatic chucking electrode S prior to the start of etching must be set to predetermined values to allow stable etching. At this time, the inside of the plasma processing chamber 100 is maintained at high vacuum state, and thus the electrostatic chucking electrode S is substantially thermally insulated. Therefore, by simply circulating coolant on the temperature adjustment unit 50, the coolant cannot be vaporized and thus the predetermined temperatures cannot be obtained. Accordingly, in the temperature adjustment unit 50 of the present embodiment, the temperature control is performed while monitoring the temperature of the electrostatic chucking electrode S with a temperature sensor 58 (a thermocouple), and while the control system 56 controls the output of the heating unit 54, the opening degree of the expansion valve 53, and the output of the compressor 52 via inverter control.

The heating unit 54 does not generate heat during plasma generation. Note that the temperature sensor 58 may monitor the temperature of another member or directly monitor the temperature of the coolant in the case where high frequency is directly applied to the electrostatic chucking electrode S.

This, while the temperature adjusting unit 50 has a relatively narrow temperature control range due to the coolant property, it has high thermal efficiency since the electrostatic chucking electrode S is directly cooled by the coolant. The coolant in the electrode block has a relatively high heat transfer coefficient compared with thermal medium, that is, about 5000 W/m²K at 5° C., and thus it is not necessary to lower the set temperature as in the case for coolants in the conventional apparatuses. This arrangement allows the power for operating the temperature adjusting unit 50 to be reduced.

The heating unit 54 in this embodiment induces a built-in heater. However, instead of using a heater, the heating unit can utilize hot water flow. Alternatively, as shown in FIG. 3(b), the apparatus can have between the coolant supplying pipeline 51-1 and coolant discharging pipeline 51-2 a bypassing pipeline 80 that bypasses the electrode block 1, and use the bypassing pipeline 80 together with the heating unit 54 to perform the temperature control.

[Requirements for Electrode Structure when Using the Temperature Adjustment Unit]

Requirements for the structure of the electrostatic chucking electrodes when using the temperature adjustment unit 50 according to the present invention will be described. There are two main requirements. One of them relates to the resistance to the pressure of the coolant circulating in the electrode block, and the other relates to the structure of the coolant flow channel that addresses the thermal property of the coolant.

The temperature control unit 50 in this embodiment utilizes a cooling method involving vaporization of the coolant and hence has a high coolant pressure compared to the circulation-type temperature adjustment units. Thus, it requires an electrode structure that addresses the transformation in shape of the electrode block 1. It was found that if the surface in contact with the semiconductor wafer W is convexed for 0.05 mm or more, for example, leakage of He gas increases, making it impossible to perform accurate temperature control. For example, in the case where the coolant pressure is 5 atm, a load of about 3500 kg is applied onto the plane of the electrode block 1. In this case, if only the electrode block 1 and the periphery of the guide member 3 are solder bonded, the electrode block may be convexed.

Accordingly, in the electrostatic chucking electrode S of this embodiment, the guide member 3 is solder bonded 21 not only to the periphery of the electrode block 1 but also to side walls 20 (regarded as rigid members) of coolant flow channels 24 in the electrode block 1. The electrode block 1 and the guide member 3 may be bonded not only by soldering but also by brazing, diffusion bonding or electron beam welding. The guide member 3 may be formed of a material having a thermal conductivity lower than the electrode block 1. The coolant is introduced from a coolant inlet 22 into the coolant passage 6, passes through the coolant flow channels 24 between side walls 20, and is discharged through a coolant outlet 23. The side walls 20 serve as heat transfer means between the coolant and the electrode block 1 and also as a rib to enhance the strength of the electrode block 1.

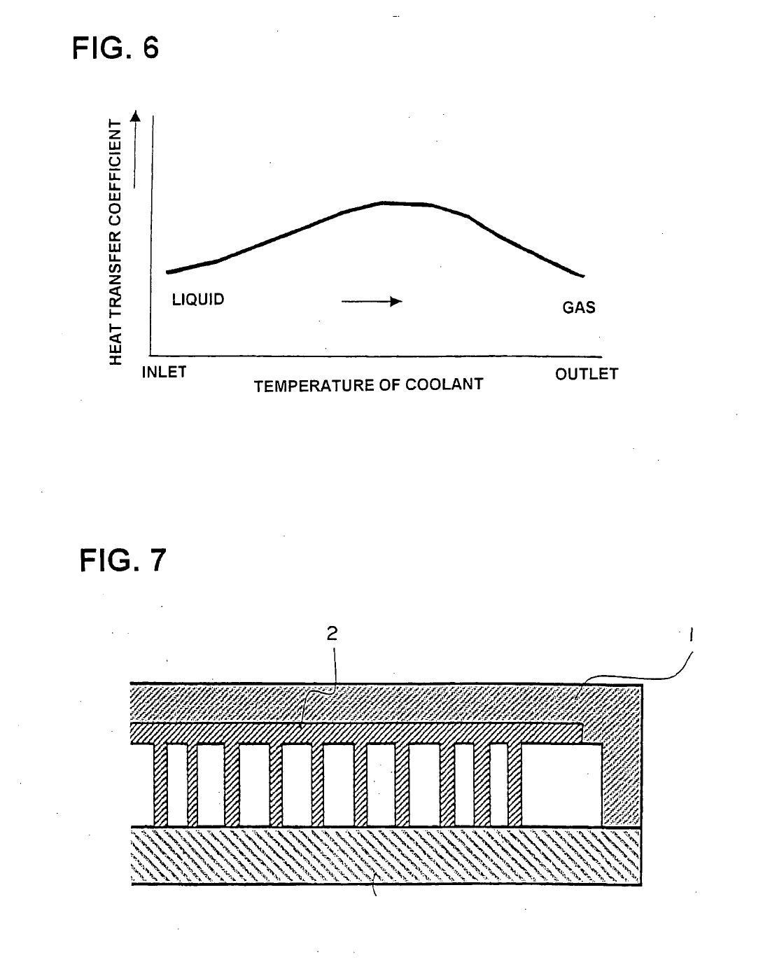

The structure for the coolant channels must be designed so that the coolant to be circulated does not rest in a certain area, and the heat transfer coefficient or the circulating coolant should be addressed. FIG. 6 shows the heat transfer coefficient of the coolant circulating in the electrode block. As shown in the figure, the coolant is in the state of liquid at the inlet of the electrode block, and then, as it passes through the electrode block, it absorbs heat and is vaporized, causing the mixing ratio of liquid and gas to change and hence causing the heat transfer coefficient during the flow to change. Accordingly, as shown in FIG. 7, a heat dissipation plate 2 (aluminum, copper, ALN) having a good thermal conductivity may be provided so that the temperature in the electrode block is uniformized.

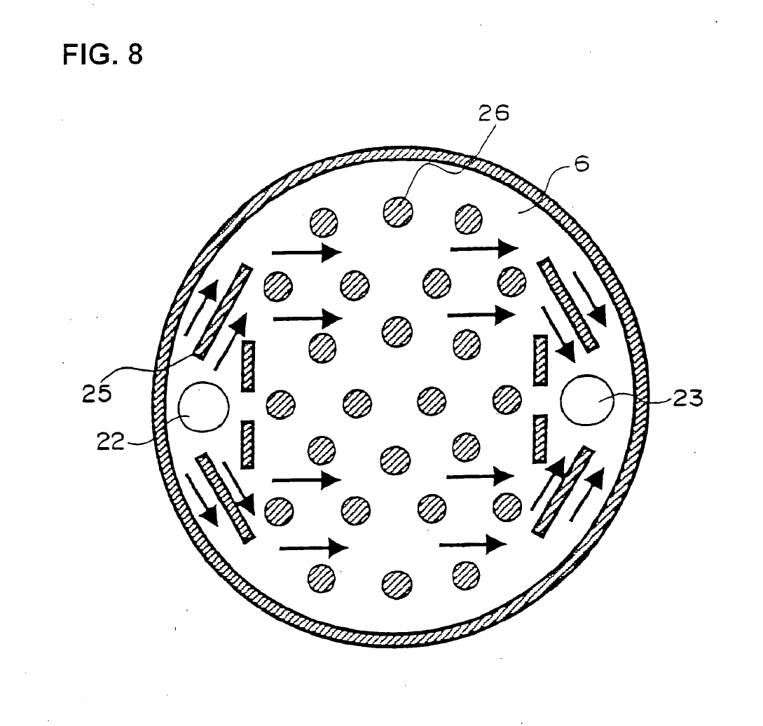

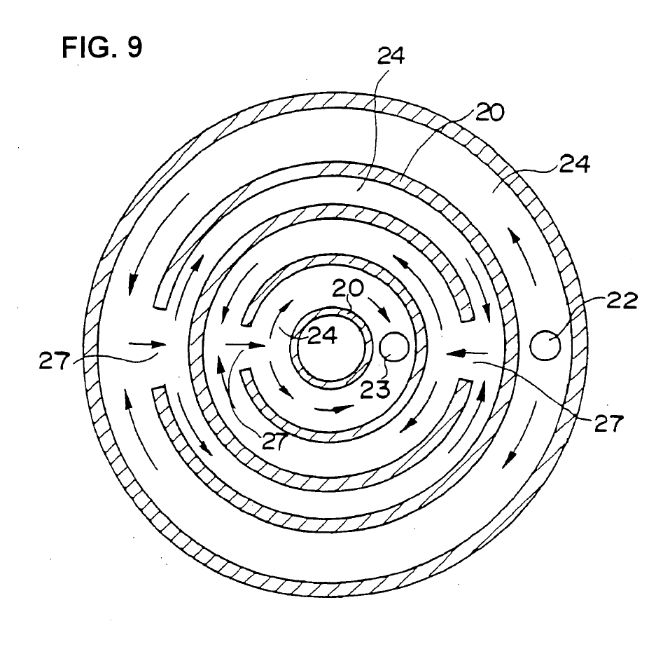

Exemplary structures of flow channels in which the coolant does not rest in a certain area are shown in FIGS. 8 and 9. In the electrostatic chucking electrode shown in FIG. 8, regulation plates 25 are provided in the electrode block so that the coolant introduced from a coolant inlet 22 is evenly distributed to reach a coolant outlet 23. Columns 26 are also provided in the electrode block in a staggered manner to enhance the rigidity.

In the structure shown in FIG. 9, a coolant inlet 22 and a coolant outlet 23 are arranged approximate each other; multiple circular side walls 20 with crenas are arranged concentrically; multiple coolant flow channels 24 are arranged along the circumferential directions; and adjacent flow channels 24 are connected via flow communication passages 27, thereby causing the coolant to circulate in circumferential directions.

[Operation for Replacing the Electrostatic Chucking Electrode]

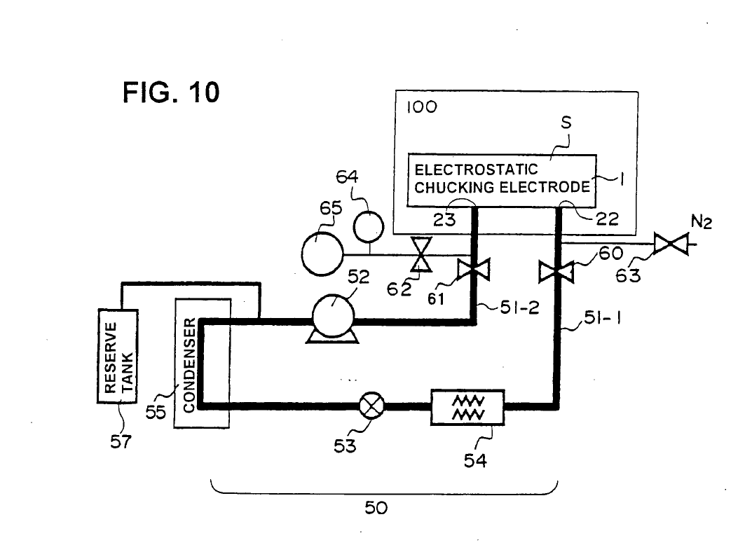

The electrostatic chucking electrode S must be replaced since it experiences the deterioration in performance (chucking performance or electrical performance) due to plasma etching and/or deposits that adhere during etching. Operation of the temperature adjustment unit 50 in the replacement of the electrostatic chucking electrode S will be described with reference to FIG. 10. The temperature adjustment unit 50 in this embodiment has a valve 60 disposed between the coolant supplying pipeline 51-1 and the coolant inlet 22 of the electrode block 1, and a valve 61 disposed between the coolant outlet 23 of the electrode block 1 and the coolant discharging pipeline 51-2. The temperature adjustment unit 50 also has a gas supply valve 63 for supplying nitrogen, for example, between the valve 60 and the coolant inlet 22, and a discharge valve 62 between the valve 61 and the coolant discharging outlet 23. A pressure sensor 64 and a vacuum pump 65 are provided in the downstream of the discharging valve 62.

The temperature adjustment unit 50 has a vacuum pump built therein so that it can automatically set itself in a node to allow the replacement of the electrostatic chucking electrode S, and after the installation, can automatically set itself in an operable mode.

When removing the electrostatic chucking electrode S, the valve 60 is closed with the coolant being circulated by the operation of the compressor 52, and after a few minutes, the valve 61 is closed. By this process, all of the coolant residing in the coolant pipeline of the electrode block 1 is retrieved into the reserve tank 57. Thereafter, the valve 62 is opened, and at the same time, the vacuum pump 65 is operated to evacuate the coolant pipeline in the electrode block 1 of the electrostatic chucking electrode S to achieve a vacuum state. The pressure sensor 64 then monitors the pressure in the coolant pipeline, and upon achieving a predetermined pressure, the valve 62 is closed and the valve 63 is opened to introduce nitrogen gas into the coolant pipeline of the electrode block 1. When the pressure in the coolant pipeline of the electrode block 1 reaches atmospheric pressure, the valve 63 is closed, and it is displayed on a control screen of the plasma processing apparatus that the electrostatic chucking electrode S is ready for replacement.

Then, the connection between the coolant inlet 22 and the coolant supplying pipeline 51-1 and the connection between the coolant outlet 23 and the coolant discharging pipeline 52 are disconnected manually, and the electrostatic chucking electrode S is then removed. Thereafter, anew electrostatic chucking electrode S is placed; the coolant inlet 22 and the coolant supplying pipeline 51-1 are connected, and the coolant outlet 23 and the coolant discharging pipeline 52 are connected, thereby completing the replacement of the electrostatic chucking electrode S.

After replacing the electrostatic chucking electrode S, the valve 62 is opened, the pump 65 is operated to evacuate the coolant pipeline in the electrostatic chucking electrode S, then the valve 62 is closed and the valves 60 and 61 are opened. It is displayed on the control screen of the plasma processing apparatus that the temperature adjustment unit 50 is ready for operation.

[Confirming Temperature of the Electrostatic Chucking Electrode]

Using the temperature adjustment unit 50 described above and a plasma processing apparatus comprising the electrostatic chucking electrode S shown in FIG. 2, the temperature of a semiconductor wafer W during plasma discharge was measured. As a result, it was confirmed that the electrostatic chucking electrode can be set to a predetermined temperature (confirmed in the range of 0 to 10° C.) during plasma discharge, and that a good repeatability in temperature can be achieved even when the power of the biasing power supply supplied to the electrostatic chucking electrode S is 3000 W, thereby proving the effectiveness of the electrostatic chucking electrode of the present invention.

What is claimed is:

1. A plasma processing apparatus for processing a wafer by using a plasma generated inside a processing chamber, the apparatus comprising:
a holder stage for holding the wafer on the surface thereof, disposed in the processing chamber;
a dielectric film disposed on the surface of the holder stage;
an electrode block for holding the wafer on the dielectric film thereon, comprising a coolant flow passage disposed thereinside for performing temperature control for controlling a temperature of the holder stage;
a cooling cycle for the coolant circulated therein including a compressor, and expansion valve and an evaporator, a heating unit disposed between the expansion valve and the evaporator which heats the coolant, and in which the electrode block is used as the evaporator of the cooling cycle; and
a control unit which adjusts a temperature of the holder stage sufficiently high for the processing of the wafer before the process controlling operations of the cooling cycle including at least the heating unit.

2. The plasma processing apparatus according to claim 1, wherein the control unit controls the cooling cycle so that the coolant is evaporated when passing inside the coolant flow passage in the electrode block.

3. The plasma processing apparatus according to claim 1, wherein the control unit adjusts the temperature of the holder stage to reduce a difference of the holder stage temperature before the start of the process and after completion of the process.

4. The plasma processing apparatus according to claim 1, wherein the control unit controls the operation of the cooling cycle including at least one of an output of the heating unit, an opening degree of the expansion valve and an output of the compressor.

5. The plasma processing apparatus according to claim 1, wherein the control unit stops the heating of the heating unit when the plasma is being generated.

6. The plasma processing apparatus according to claim 1, wherein the control unit controls the cooling cycle so that the coolant is evaporated when passing inside the coolant flow passage in the electrode block; and
the control unit controls the operation of the cooling cycle including at least one of an output of the heating unit, an opening degree of the expansion valve and an output of the compressor.

7. The plasma processing apparatus according to claim 1, wherein the control unit adjusts the temperature of the holder stage to reduce a difference of the holder stage temperature before the start of the process and after completion of the process; and
the control unit controls the operation of the cooling cycle including at least one of an output of the heating unit, an opening degree of the expansion valve and an output of the compressor.

8. The plasma processing apparatus according to claim 1, wherein the control unit controls the cooling cycle so that the coolant is evaporated when passing inside the coolant flow passage in the electrode block; and
the control unit stops the heating of the heating unit when the plasma is being generated.

9. The plasma processing apparatus according to claim 1, wherein the control unit adjusts the temperature of the holder stage to reduce a difference of the holder stage temperature before the start of the process and after completion of the process; and
the control unit stops the heating of the heating unit when the plasma is being generated.

10. The plasma processing apparatus according to claim 1, wherein the control unit controls the cooling cycle so that the coolant is evaporated when passing inside the coolant flow passage in the electrode block;
the control unit controls the operation of the cooling cycle including at least one of an output of the heating unit, an opening degree of the expansion valve and an output of the compressor; and
the control unit stops the heating of the heating unit when the plasma is being generated.
